(19) United States
(12) Patent Application Publication
(10) Pub. No.: US 2022/0393438 A1
(43) Pub. Date: Dec. 8, 2022

(54) OPTOELECTRONIC SEMICONDUCTOR COMPONENT, ARRANGEMENT OF OPTOELECTRONIC SEMICONDUCTOR COMPONENTS, OPTOELECTRONIC DEVICE AND METHOD FOR PRODUCING AN OPTOELECTRONIC SEMICONDUCTOR COMPONENT

(71) Applicant: OSRAM Opto Semiconductors GmbH, Regensburg (DE)

(72) Inventors: Stefan ILLEK, Donaustauf (DE); Hubert HALBRITTER, Dietfurt-Toeging (DE)

(21) Appl. No.: 17/773,322

(22) PCT Filed: Oct. 26, 2020
(86) PCT No.: PCT/EP2020/080063

§ 371 Date: Apr. 29, 2022

(30) Foreign Application Priority Data
Oct. 30, 2019 (DE) 10 2019 216 710.1

(51) Int. Cl. H01S 5/34; H01S 5/183

(52) U.S. Cl. CPC H01S 5/3407; H01S 5/18344

(57) ABSTRACT

The invention relates to a semiconductor laser apparatus having a layer stack which comprises a first resonator mirror, a second resonator mirror and an active zone which is arranged between the first and second resonator mirrors and which is suitable for emitting electromagnetic radiation. A charge carrier barrier is arranged around a central region of the active zone.

### CROSS-REFERENCE TO RELATED APPLICATIONS

This patent application is a national stage entry from International Application No. PCT/EP2020/080063, filed on Oct. 26, 2020, published as International Publication No. WO 2021/083840 A1 on May 6, 2021, and claims priority under 35 U.S.C. § 119 from German patent application 10 2019 216 710.1, filed Oct. 30, 2019, the entire contents of all of which are incorporated by reference herein.

### BACKGROUND

Surface emitting lasers, i.e. laser devices in which the laser light generated is emitted perpendicularly to a surface of a semiconductor layer arrangement, can be commonly used as a laser light source, for example in display devices.

Generally, concepts are sought which allow the pixel size of emitters to be reduced.

### SUMMARY

The present invention is based on the object of providing an improved semiconductor laser device. The present invention is furthermore based on the object of providing an improved arrangement of semiconductor laser devices, an improved optoelectronic component and also an improved method for producing a semiconductor laser device.

In accordance with embodiments, the object is achieved by means of the article and the method in the independent patent claims.

Advantageous further developments are defined in the dependent claims.

A semiconductor laser device has a layer stack comprising a first resonator mirror, a second resonator mirror and also an active zone arranged between the first and second resonator mirrors and suitable for emitting electromagnetic radiation. A charge carrier barrier is arranged around a central region of the active zone. By way of example, the current flow through the active zone can be locally delimited by said charge carrier barrier.

By way of example, a part of the layer stack is structured to form a mesa, and the charge carrier barrier is arranged in each case in an edge region of the mesa.

In accordance with embodiments, the charge carrier barrier is produced by local dopant diffusion and/or local quantum well intermixing. By way of example, the band gap energy of the active zone in the central region can differ from that in the region of the charge carrier barrier.

One or more active layers of the active zone of an optoelectronic semiconductor component are usually undoped or weakly doped (e.g. light n-type doping, abbreviated to n⁻), that is to say that for example (in a vertical direction) a p-i-n junction is present, where i stands for intrinsic. For the lateral movement of charge carriers there is then no barrier in the at least one layer of the active zone. The local diffusion into an undoped or weakly doped layer has the effect that a significantly higher doping (for example a p-type doping) forms in the diffused region, that is to say that laterally e.g. a p+/i junction or p⁺/n⁻ junction arises, which reduces the diffusion of electrons toward a mesa edge. Alternatively, one or more layers of the active zone (e.g. quantum well layers) may originally be present in a doped form, with the result that an n/p⁺ junction forms laterally instead of (in the case of the undoped layer described above) an i/p⁺ junction and constitutes a higher barrier for electrons in comparison with the i/p⁺ junction.

The local dopant diffusion accordingly makes it possible, in one or more otherwise (i.e. apart from the local increase in the doping mentioned below) undoped or intrinsically doped layers, in particular quantum well layers, of the active zone (110), to locally increase a doping so that a lateral pn junction arises as a result. In particular, a partial region of the at least one layer of the active zone can be doped in such a way that a diffusion voltage of the resulting lateral pn junction is formed as a result and in turn a charge carrier barrier for electrons is produced as a result. In other words, a lateral diffusion voltage is produced by the local substitution of individual atoms of at least one layer of the active zone (e.g. at least one quantum well layer) by the dopant.

The doping can be increased locally e.g. to 1·10¹⁷/cm³ to 5·10¹⁸/cm³, preferably to 5·10¹⁷/cm³ to 1·10¹⁸/cm³.

By means of the local dopant diffusion, local quantum well intermixing can be produced at the same time given suitable process control, such that the band gap energy of the active zone in the central region (107) differs from that in the region of the charge carrier barrier (118), which likewise contributes to the charge carrier barrier for electrons. The change in the band gap by means of exchanging lattice atoms between quantum well and quantum barrier layers is also referred to as intermixing of the quantum well structures in the active zone, and if this process is mediated via the introduction of impurity atoms as in the present case, then this is called “impurity induced quantum well intermixing”.

By way of example, a lateral dimension of the semiconductor laser device is less than 10 μm.

The semiconductor laser device can furthermore comprise a buried oxide layer, wherein the buried oxide layer has an opening in a central region of the semiconductor laser device. The buried oxide layer can be arranged for example between the first resonator mirror and the active zone. However, it can also be arranged at other locations in the layer stack.

The buried oxide layer can be produced by oxidation of a semiconductor layer, e.g. an Al-containing semiconductor layer, from an edge region of the mesa. In this case, the oxidation time can be dimensioned such that a non-oxidized region of this conductive semiconductor layer remains in a central region of the layer stack and constitutes an opening.

Adjacent semiconductor laser devices are separated from one another in each case by trenches.

The trenches can extend at most as far as an upper edge of the active zone and not sever the active zone.

In accordance with further embodiments, the trenches sever the active zones of adjacent semiconductor laser devices.

The trenches have for example a maximum lateral dimension of less than 10 μm.

In accordance with further embodiments, an optoelectronic device comprises an arrangement as described above and also a control device suitable for individually controlling semiconductor laser devices of the arrangement.

In accordance with further embodiments, a display device comprises the optoelectronic device as defined above.

A method for producing an arrangement of semiconductor laser devices comprises forming trenches in a layer stack comprising a first resonator mirror, a second resonator mirror and also an active zone arranged between the first and second resonator mirrors. A mesa is structured as a result. The method furthermore comprises forming a charge carrier barrier in an edge region of the mesa.

By way of example, forming the charge carrier barrier can be effected by diffusion of dopants in the trenches.

In accordance with embodiments, the trenches extend at most as far as the upper edge of the active zone.

In accordance with further embodiments, the trenches extend at least as far as the lower edge of the active zone.

The person skilled in the art will recognize additional features and advantages after reading the following detailed description and examining the accompanying drawings.

### BRIEF DESCRIPTION OF THE DRAWINGS

The accompanying drawings serve to afford an understanding of exemplary embodiments of the invention. The drawings illustrate exemplary embodiments and together with the description serve to elucidate same. Further exemplary embodiments and numerous advantages from among those intended are evident directly from the following detailed description. The elements and structures shown in the drawings are not necessarily illustrated in a manner true to scale with respect to one another. Identical reference signs refer to identical or mutually corresponding elements and structures.

FIG. 1 shows a schematic cross-sectional view of a semiconductor laser device in accordance with embodiments.

FIG. 2 shows a schematic cross-sectional view of a semiconductor laser device in accordance with further embodiments.

FIGS. 3A to 3C illustrate a workpiece during the implementation of a method for producing a semiconductor laser device in accordance with embodiments.

FIGS. 4A to 4B illustrate a workpiece during the implementation of a method for producing a semiconductor laser device in accordance with further embodiments.

FIG. 5 shows a schematic cross-sectional view of an optoelectronic device in accordance with embodiments.

FIG. 6 shows a schematic cross-sectional view of an optoelectronic device in accordance with further embodiments.

FIG. 7 summarizes a method in accordance with embodiments.

### DETAILED DESCRIPTION

In the following detailed description, reference is made to the accompanying drawings, which form part of the disclosure and show specific exemplary embodiments for illustration purposes. In this context, a direction terminology such as “top side”, “bottom”, “front side”, “rear side”, “over”, “on”, “in front of”, “behind”, “at the front”, “at the back”, etc. relates to the orientation of the figures currently being described. Since the components parts of the exemplary embodiments can be positioned in different orientations, the direction terminology serves only for elucidation and is not restrictive in any way.

The description of the exemplary embodiments is not restrictive since other exemplary embodiments also exist and structural or logical changes can be made, without in that case departing from the scope defined by the patent claims. In particular, elements of exemplary embodiments described below can be combined with elements of other exemplary embodiments from among those described, provided that nothing to the contrary is evident from the context.

The terms “wafer” or “semiconductor substrate” used in the following description can encompass any semiconductor-based structure having a semiconductor surface. Wafer and structure should be understood as including doped and undoped semiconductors, epitaxial semiconductor layers, if appropriate carried by a base support, and further semiconductor structures.

By way of example, a layer composed of a first semiconductor material can be grown on a growth substrate composed of a second semiconductor material, for example a GaAs substrate, a GaN substrate or an Si substrate, or composed of an insulating material, for example on a sapphire substrate.

Depending on the purpose of use, the semiconductor can be based on a direct or an indirect semiconductor material. Examples of semiconductor materials that are particularly suitable for generating electromagnetic radiation encompass, in particular, nitride semiconductor compounds, which can generate ultraviolet light, blue light or light of longer wavelength, for example, such as GaN, InGaN, AIN, AlGaN, AlGaInN, AlGaInBN, for example, phosphide semiconductor compounds, which can generate green light or light of longer wavelength, for example, such as GaAsP, AlGaInP, GaP, AlGaP, InGaAsP, for example, and further semiconductor materials such as GaAs, AlGaAs, InGaAs, AlInGaAs, SiC, ZnSe, ZnO, Ga2O3, diamond, hexagonal Bn and combinations of the materials mentioned. The stoichiometric ratio of the compound semiconductor materials can vary. Further examples of semiconductor materials can encompass silicon, silicon-germanium and germanium. In the context of the present description, the term “semiconductor” also includes organic semiconductor materials.

The term “substrate” generally encompasses insulating, conducting or semiconductor substrates.

The terms “lateral” and “horizontal”, as used in this description, are intended to describe an orientation or alignment which extends substantially parallel to a first surface of a substrate or semiconductor body. This can be the surface of a wafer or of a chip (die), for example.

The horizontal direction can lie for example in a plane perpendicular to a growth direction during the growth of layers.

The term “vertical”, as used in this description, is intended to describe an orientation which extends substantially perpendicular to the first surface of a substrate or semiconductor body. The vertical direction can correspond for example to a growth direction during the growth of layers.

Insofar as the terms “have”, “contain”, “encompass”, “comprise” and the like are used here, they are open terms which indicate the presence of the stated elements or features, but do not exclude the presence of further elements or features. The indefinite articles and the definite articles encompass both the plural and the singular, provided that something to the contrary is not clearly evident from the context.

In the context of this description, the term “electrically connected” denotes a low-resistance electrical connection between the connected elements. The electrically connected elements need not necessarily be directly connected to one another. Further elements can be arranged between electrically connected elements.

The term “electrically connected” also encompasses tunnel contacts between the connected elements.

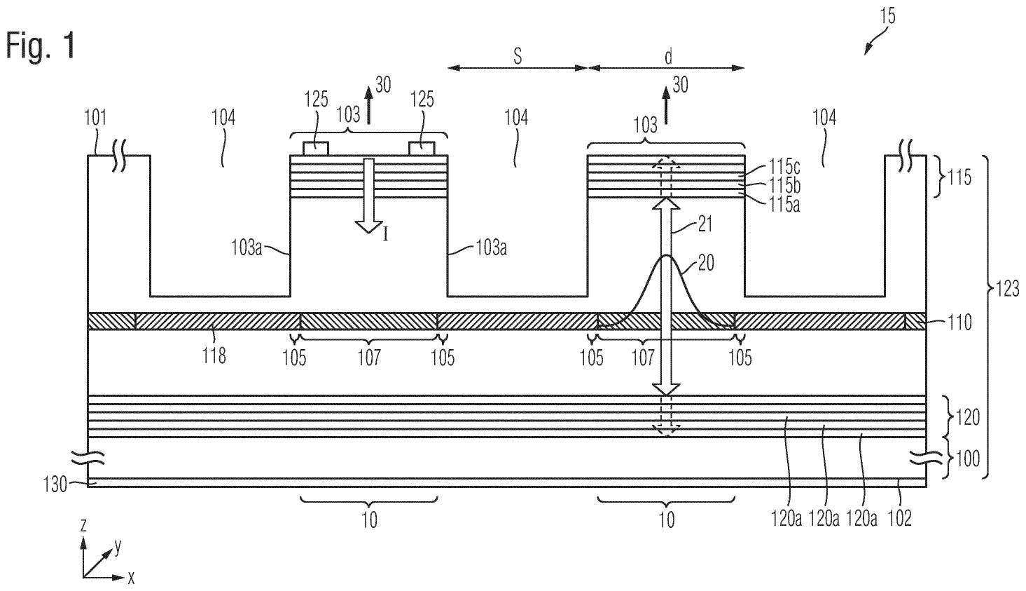

FIG. 1 shows a schematic cross-sectional view of an arrangement 15 of a plurality of semiconductor laser devices 10 on a common substrate 100. The semiconductor laser device 10 has a layer stack 123. The layer stack 123 comprises a first resonator mirror 115, a second resonator mirror 120 and also an active zone 110 arranged between the first and second resonator mirrors 115, 120. The active zone 110 is suitable for emitting electromagnetic radiation. A charge carrier barrier 118 is arranged around a central region 107 of the active zone 110.

The active zone can have for example a quantum well structure, for example a single quantum well (SQW) structure or a multi quantum well (MQW) structure for generating radiation. In this case, the designation “quantum well structure” does not exhibit any significance with regard to the dimensionality of the quantization. It therefore encompasses, inter alia, quantum wells, quantum wires and quantum dots and any combination of these layers.

In the case of the arrangement shown in FIG. 1, the layer stack 123 is structured to form mesas 103. Adjacent mesas 103 are separated from one another in each case by a trench 104. In this case, the term “edge region” used in the context of the description denotes an edge of the respective mesa 103. By contrast, the central region 107 of the semiconductor laser device is arranged in a middle or central region of the respective mesa 103.

A charge carrier barrier 118 is arranged in an edge region 105 of the mesa 103. In this context, the term “charge carrier barrier” denotes a region in which the band structure of the active zone is changed in comparison with the central region 107 of the mesa. By way of example, owing to a dopant diffusion, a lateral pn junction is formed in the region of the active zone. In addition, the band gap of the quantum well structure in the region of the charge carrier barrier can be increased by comparison with the band gap in the central region. This accordingly results in a changed, for example increased, band gap energy in the edge region of the active zone. By virtue of the fact that the charge carrier barrier is arranged in the edge region of the semiconductor laser device, a lateral diffusion of the charge carriers from the central region of the active zone is reduced.

In this case, the mesas 103 are structured by trenches 104 both in the x-direction and in the y-direction. A dimensioning of the mesas 103 can be chosen such that the individual mesas are formed for example in square, rectangular, hexagonal or round fashion in plan view.

The first resonator mirror 115 can have respectively alternately stacked first layers 115a or a first composition and second layers 115b of a second composition. The second resonator mirror 120 can likewise have alternately stacked layers 120a, 120b each having a difference composition.

The respectively alternately stacked layers of the first or second resonator mirror 115, 120 each have different refractive indices. By way of example, the layers can alternately have a high refractive index (n>3.1) and a low refractive index (n<3.1) and be formed as a Bragg reflector.

By way of example, the layer thickness can be λ/4 or a multiple of λ/4, where λ indicates the wavelength of the light to be reflected in the corresponding medium. The first or the second resonator mirror 115, 120 can have 2 to 50 individual layers, for example. A typical layer thickness of the individual layers can be approximately 30 to 150 nm, for example 50 nm. The layer stack can furthermore contain one or two or a plurality of layers which are thicker than approximately 180 nm, for example thicker than 200 nm. By way of example, the second resonator mirror 120 can have a total reflectivity of 99.8% or more for the laser radiation. The first resonator mirror 115 can be formed as an output coupling mirror for the radiation from the resonator and has for example a lower reflectivity than the second resonator mirror.

Electromagnetic radiation generated in the active zone 110 can be reflected between the first resonator mirror 115 and the second resonator mirror 120 in such a way as to form in the resonator a radiation field 21 for the generation of coherent radiation (laser radiation) by way of induced emission in the active zone. Overall, the distance between the first and second resonator mirrors 115, 120 corresponds to at least half the effective emitted wavelength λ/2n, where n corresponds to the refractive index of the active zone), such that standing waves can form within the resonator. The laser radiation 30 generated can be coupled out of the resonator via the first resonator mirror 115, for example. The semiconductor laser device 10 thus forms a so-called VCSEL, i.e. vertical cavity surface emitting laser.

In accordance with embodiments, the alternately stacked layers for forming the first and/or second resonator mirror 115, 120 can comprise semiconductor layers, at least one layer of which is doped in each case. By way of example, at least one semiconductor layer of the stacked layers of the first resonator mirror 115 can be doped with a first conductivity type, for example p- or n-type. In a corresponding manner, at least one of the semiconductor layers of the second resonator mirror 120 can be doped with dopants of a second conductivity type, which is different than the first conductivity type, for example n- or p-type.

In accordance with further embodiments, at least the first or the second resonator mirror 115, 120 can be constructed exclusively from dielectric layers. In this case, the layer stack 123 additionally has a first semiconductor layer (not shown) of the first conductivity type and also a second semiconductor layer of a second conductivity type (not shown). By way of example, in this case, the alternately arranged dielectric layers can alternately have a high refractive index (n>1.7) and a low refractive index (n<1.7) and be embodied as a Bragg reflector.

By way of example, the semiconductor layers of the first and second resonator mirrors and also of the active zone can be based on the InGaAlP material system and comprise semiconductor layers of the composition InₓGa_{y}Al_{1-x-y}P where 0≤x, y≤1 and x+y≤1.

In accordance with further embodiments, the semiconductor layers of the first and second resonator mirrors and also of the active zone can be based on the AlGaAs layer system and contain in each case layers of the composition AlₓGal₁₋ₓAs, where 0≤x≤1.

The semiconductor laser device 10 furthermore has a first electrical contact element 125 and also a second electrical contact element 130. By way of example, the layers of the first resonator mirror 115 are connected to the first electrical contact element 125. Charge carriers of a first conduction type (e.g. holes) are able to be impressed via the first electrical contact element 125.

Furthermore, the layers of the second resonator mirror 120 can be connected to the second electrical contact element 130. Charge carriers of a second conduction type (e.g. electrons) can be impressed via the second electrical contact element 130. The semiconductor laser device is electrically pumpable by a suitable voltage being applied between the first and second contact elements 125, 130. By way of example, a semiconductor substrate 100 can be arranged between the second resonator mirror 120 and the second contact element 130.

Examples of materials of the substrate 100 comprise a suitable growth substrate for growing the semiconductor materials mentioned above. By way of example, the material of the semiconductor substrate 100 can be GaAs or some other suitable growth material.

By virtue of the fact that, as explained above, the charge carrier barrier 118 is arranged in an edge region 105 of the semiconductor laser device 10, it is possible to guide the current path within the semiconductor layer structure 123 in a targeted manner. The lateral diffusion of the charge carriers is reduced. Accordingly, the emission of electromagnetic radiation takes place in particular in the central regions 107 of the semiconductor laser device 10, and an optical mode 20 forms.

By virtue of a lateral diffusion of the charge carriers being reduced, the surface recombination in the region of the mesa edge 103a is reduced. As a consequence, it is possible to realize a semiconductor laser device 10 with a smaller pixel size d or width of the mesa 103. By way of example, a mesa width d of less than 5 μm or less can be realized.

For example, the mesa width can be less than 10 μm, for example less than 2 μm. For example, the mesa width d can be at least 1 μm. Furthermore, it is possible to reduce the distance s between adjacent mesas 103 to a value of less than 10 μm. For example, the distance s can also be less than 5 μm. The distance s can be greater than 1 μm.

As a consequence, it is possible to increase the fill factor for arrangements of semiconductor laser devices 10. Introducing the charge carrier barrier 118 results in an improved overlap of the regions with high charge carrier concentration with the optical mode 20 of the semiconductor laser device. A higher gain and a lower threshold current of the semiconductor laser device are achieved as a consequence. Furthermore, lower losses, higher efficiency and a lower threshold current of the semiconductor laser device are achieved on account of the reduced surface combination.

In FIG. 1, a current impressing direction is represented schematically by I. Furthermore, an optical mode 20 and also the formation of a standing wave by a radiation field 21 are indicated.

The charge carrier barrier 118 for the lateral charge carrier diffusion can be produced by a local indiffusion of dopants. As already mentioned, in the case of the charge carrier barrier the band gap and in particular the profile of conduction and valence bands is increased or decreased, such that the lateral diffusion of the charge carriers is reduced. Generally a dopant, such as zinc, magnesium or some other element of group II, for example, is introduced into the III-V semiconductor material. As a result of the introduction of the dopant, firstly the profile of the conduction and/or valence band is changed. For example, an n⁻/p⁺ junction forms, which constitutes a barrier for electrons. Furthermore, during the diffusion process, a self-diffusion of lattice atoms in the quantum well layers can be initiated, which causes an increase in the band gap and thus a further increase in the lateral charge carrier barrier. This changing of the band gap by introducing dopants (“impurities”) is also referred to as “Impurity Induced Quantum Well Intermixing”.

In this case, it is not the defects that produce a change in the band structure, but rather the self-diffusion of lattice atoms of the quantum well layers. The latter consist of wells and barriers which differ in their composition, e.g. InGaAlP with differing Al content. If the Al difference between barrier and well is reduced by the intermixing process, then the band gap changes. Defects in the crystal are necessary for this self-diffusion of lattice atoms. Said defects can arise at high temperatures as a result of detachment of individual lattice atoms from the crystal (with the formation then of a vacancy in the lattice and an atom at an interstitial site). In this case, the doping ratios are not changed. This is therefore referred to as “impurity free intermixing”, which is advantageous e.g. on account of low absorption in the optical semiconductor and is therefore used e.g. in lasers for producing non-absorbing regions at the laser facet. The introduction of suitable dopants firstly substitutes lattice atoms and thus produces interstitial atoms required for the self-diffusion, and secondly, by way of increasing the doping, influences the detachability of precisely these defects, which corresponds to their probability of existence. The activation energy for this self-diffusion can thus be significantly reduced and the intermixing process can therefore take place at lower temperatures. It is advantageous, moreover, if by choosing a suitable process atmosphere during the diffusion procedure the process control is chosen so as to support the formation of the defects required for the quantum well intermixing.

In the present case, intermixing barrier and doping barrier thus interact and the disadvantages of slightly increased optical losses can be accepted for a better performance (e.g. smaller pixel size) of the component.

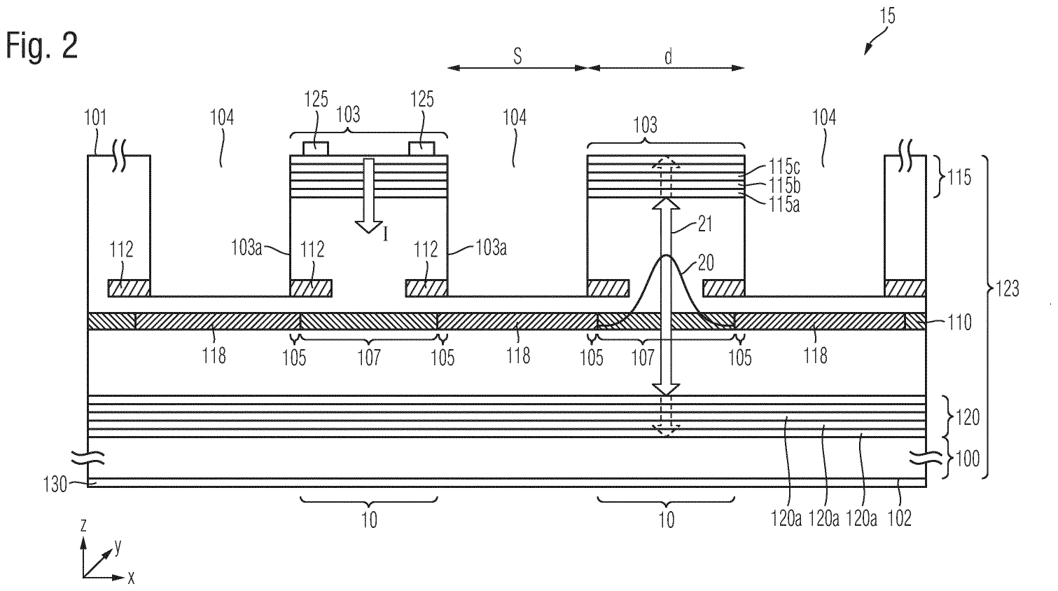

FIG. 2 shows a schematic cross-sectional view of an arrangement of semiconductor laser devices 10 in accordance with further embodiments. In addition to the component parts of the semiconductor laser devices 10 illustrated in FIG. 1, here buried oxide layers 112 are arranged in an edge region 105 of the respective mesas 103 or of the semiconductor laser device 10. The buried oxide layer 112 can be produced for example by oxidation of the semiconductor material, for example of a sidewall of the mesa 103.

In this case, the buried oxide layer 112 constitutes the oxide aperture usually used. The buried oxide layer 112, which is not present in a central region 107 of the semiconductor laser device 10, is arranged for example between the active zone 110 and the first resonator mirror 115. However, it can also be arranged elsewhere within the layer stack 123. With the presence of the buried oxide layer 112, an additional optical confinement of the optical mode 20 can be achieved since the buried oxide layer 112 has a different refractive index than the adjoining semiconductor layer. Generally the oxide aperture 112 constricts the current flow to the central region of the mesa, but does not prevent the lateral diffusion of charge carriers in the active zone 110 to the mesa edge. The combination with the charge carrier barrier as illustrated here allows a significantly smaller distance between the mesa edge and the central region and thus laser devices 10 having significantly smaller lateral dimensions.

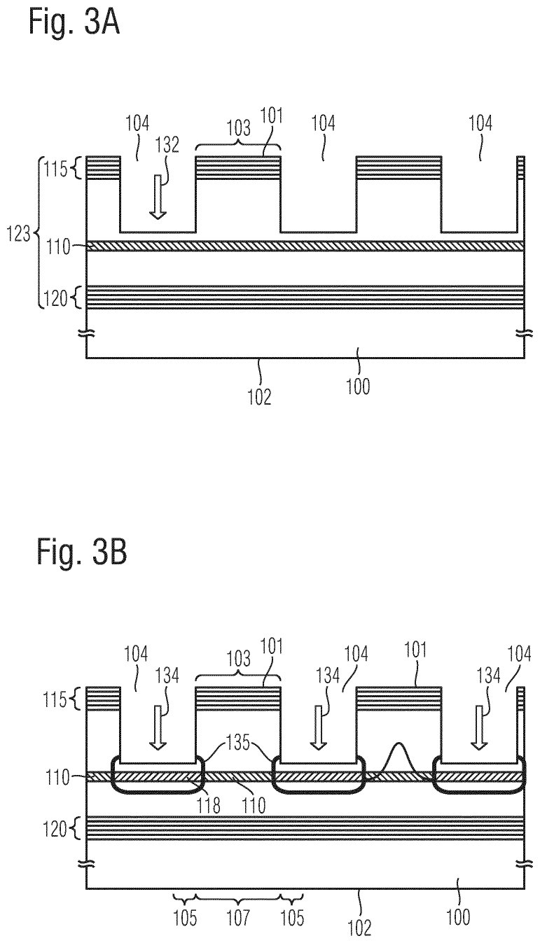

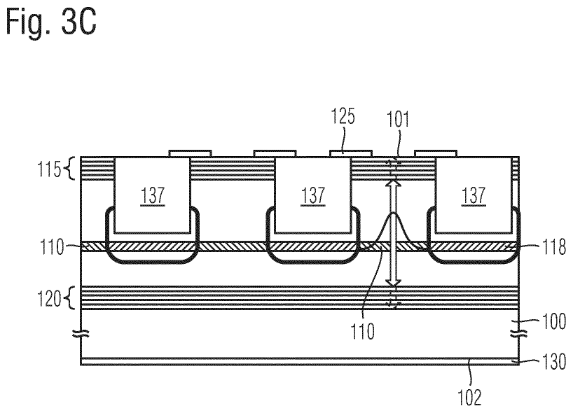

FIGS. 3A to 3C illustrate a method for producing a semiconductor laser device 10 or an arrangement 15 of semiconductor laser devices 10.

The starting point for carrying out a method is a workpiece having a layer stack 123. The layer stack comprises a first resonator mirror 115, a second resonator mirror 120 and also an active zone 110 arranged between the first and second resonator mirrors 115, 120. By way of example, the layer stack can be arranged on a growth substrate 100.

Firstly, as is illustrated in FIG. 3A, trenches 104 are formed, for example by etching, in a first main surface 101 of the workpiece, for example in a main surface of the layers which constitute the first resonator mirror 115.

By way of example, this etching can be effected with the aid of a photolithographically patterned mask which covers regions of the workpiece that are not to be etched and leaves open regions that are to be etched. By way of example a hard mask containing silicon dioxide, silicon nitride or a combination of these materials can be used for the etching. This hard mask covers the surface of the mesa 103 and can also be used as protection during a subsequent diffusion process. By way of example, openings of the mask can have a dimensioning corresponding to the distance between the mesas 103 to be defined. Furthermore, a dimensioning of the covered part can correspond to a dimensioning of the mesas 103 to be produced. The etching depth is dimensioned such that the trenches 104 do not extend as far as the active zone 110. The etching, which can be an anisotropic etching, for example, is represented by the arrow 132 in FIG. 3A.

A process for local dopant diffusion 134 through the defined trenches 104, in particular through a bottom region of the trenches 104, is subsequently carried out. As already mentioned, the local diffusion of dopants can be effected with zinc, magnesium or some other element of group II, for example.

The diffusion can be effected from the gas phase, for example. In accordance with embodiments, a precursor material or the decomposition products thereof can also be deposited on the semiconductor material and subsequently be diffused. By way of example, the diffusion can take place at low temperatures, such that the semiconductor component is not damaged, or not damaged very much, by the diffusion process.

As a result of the diffusion process, as illustrated in FIG. 3B, a charge carrier barrier 118 is produced in an edge region of the mesa 103. FIG. 3B furthermore shows an extent of a diffusion region 135, i.e. a limit as far as which for example the dopants can diffuse. As is illustrated in FIG. 3B, the diffusion regions 135 are arranged with a somewhat wider lateral extent than the width of the trenches 134. As a consequence, the charge carrier barrier extends right into an edge region of the mesa 103.

In a central region 107 of the mesa 103, the active zone 110 remains with a largely unchanged band structure. Optionally, a local oxidation can subsequently be carried out in order that, in the edge region 107 of the mesa 103, the oxide layer 112 illustrated in FIG. 2 is produced from the sidewall of the trenches 104.

In a subsequent step, as is illustrated in FIG. 3C, a filling material 137 can be introduced into the trenches 104 and planarized in order subsequently to enable a simpler contacting. Examples of the filling material 137 comprise for example BCB (benzocyclobutene), silicon oxide or other insulating materials.

Furthermore, first contact regions 125 can be provided over the first main surface 101 of the material.

For example, a transparent conductive material, for example a conductive metal oxide, can be applied and correspondingly structured. Furthermore, for example, a second contact region 130 can be applied to the second main surface 102 of the workpiece.

In accordance with embodiments, after the diffusion process has been carried out, a further etching process can be carried out in order to separate or isolate the active zones 110 of adjacent semiconductor laser devices 10 from one another.

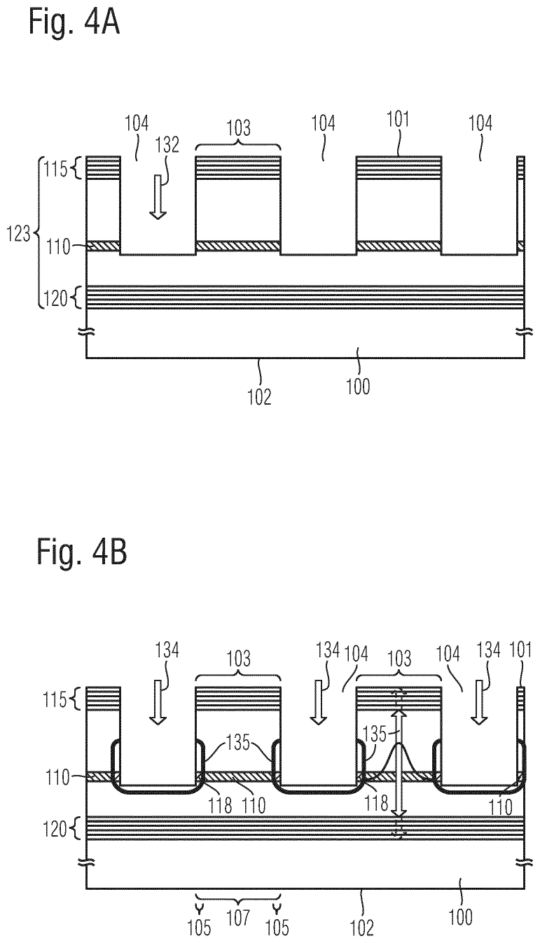

FIGS. 4A and 4B illustrate a method for producing a semiconductor laser device in accordance with further embodiments. In a departure from the embodiments illustrated in FIGS. 3A and 3B, in accordance with these embodiments the etching 132 is carried out down to a depth situated below the lower edge of the active zone 110. As a consequence, the active zone 110 is locally severed, as is illustrated in FIG. 4A.

Afterward, as is illustrated in FIG. 4B, the local diffusion of dopants 134 is carried out. This method can be carried out in a manner similar to that as explained with reference to FIG. 3B. As a consequence, the charge carrier barrier 118 extends from the trenches 104 laterally into the active zone 118. This is illustrated in FIG. 4B, which in turn illustrates the diffusion region 135. As a result, in a manner analogous to that in FIG. 3B, a charge carrier barrier 118 is produced in an edge region 105 of the mesa. In a central region 107 of the mesa 103, the active zone 110 is in each case present with a substantially unchanged band structure.

Afterward, the semiconductor laser device can be processed further in a manner corresponding to that as explained with reference to FIG. 3C. A filling material can be introduced into the trenches 104 and planarized. Furthermore, the contact regions 125, 130 can be provided.

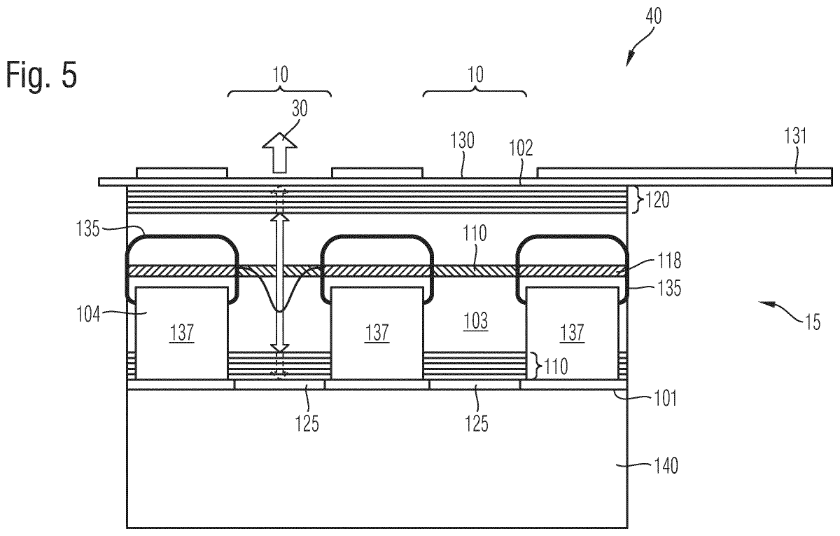

FIG. 5 shows an optoelectronic device 40 comprising an arrangement 15 of semiconductor laser devices 10 as explained above in accordance with embodiments. For example, as explained above, the filling material 137 is introduced into the trenches 104.

Furthermore, the first contact regions 125 are formed. For example, the first contact regions 125 can be formed over the respective mesas 103. A rebonding process can be carried out, by means of which the workpiece can be rebonded onto a carrier 140, which can contain any desired material selected according to the requirements of the component. For example, the carrier 140 can contain an insulating material or a semiconductor material, for example germanium or silicon. Furthermore, the first contact regions 125 can be individually drivable, for example via an external driver arranged outside the carrier 140.

After the rebonding of the workpiece onto the carrier 140, the growth substrate can be removed. Furthermore, second contact elements can be provided on the second main surface of the workpiece. For example, a transparent conductive layer can be applied as a second contact region 130. A metal of the second contact region 130 can contain for example a conductive metal oxide, for example ITO (indium tin oxide). Furthermore, a second contact element 131 can be formed over the second contact region 130. For example, a conductive layer, for example a metallic layer, can be structured so that the metallic regions of the second contact element 131 are present in regions of the trenches 104, while regions over the mesa 103 are in each case uncovered.

As illustrated in FIG. 5, for example the light emission 30 can be effected via the second main surface 102 of the optoelectronic device. In accordance with FIG. 5, a second contact region 130 is provided for the arrangement 15 of a plurality of semiconductor laser devices 10. The second contact region 130 can be contacted via the second contact element 131. The individual semiconductor laser devices 10 are in each case individually drivable via the first contact regions 125.

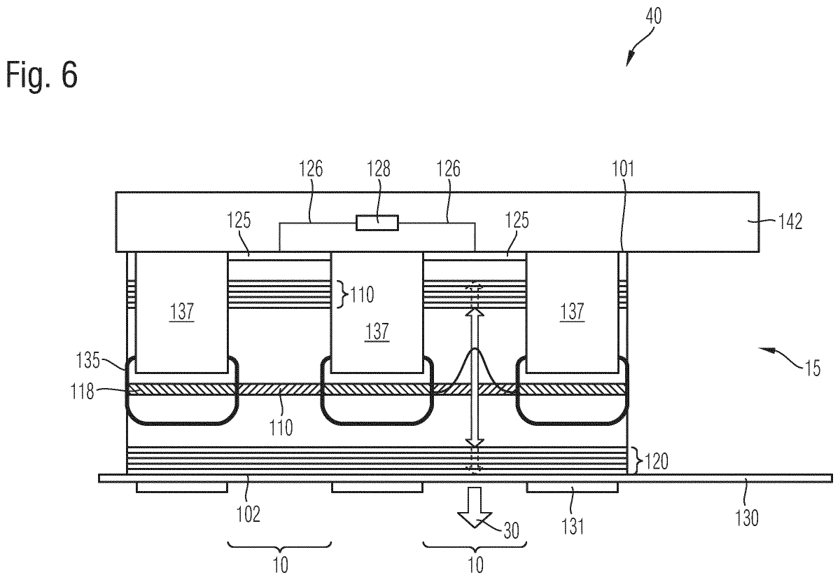

FIG. 6 shows an optoelectronic device in accordance with further embodiments. The optoelectronic device 40 again comprises an arrangement 15 of semiconductor laser devices 10. A circuit substrate 142 with a drive circuit 128 is applied over the first main surface 101 of the workpiece. For example, an ASIC (“application-specific integrated circuit”) can be provided in the circuit substrate 142. The circuit substrate 142 can be a silicon substrate, for example, in which corresponding circuit components are formed. As a result, a drive circuit 128 is provided, which can individually drive in each case the first contact elements 126 that are respectively electrically connected to the first contact regions 125.

In a manner similar to that as described with reference to FIG. 5, a common second contact region 130 can be applied on a second main surface of the workpiece. Furthermore, second contact elements 131 can be arranged over the second contact region 130. The second contact regions 130 are thus arranged between the second contact elements 131 and the second main surface 102. The second contact elements 131 can be structured in each case. A light emission 30 can be effected via the second main surface 102 of the optoelectronic device.

As a result, it is possible to realize for example an individually addressable p-pixel display or micro-display with the advantage of a directional emission.

For example, the optoelectronic device can be a display device comprising a multiplicity of emitters. The emitters can for example each correspond to a light-emitting element in an individual mesa 103. The display device can comprise for example more than 100×100 emitters, for example 1000×1000 emitters.

The individual emitters can each have a size of less than 10 μm, for instance 1 μm and a spacing of less than 10 μm, for example 4.5 μm. Accordingly, an optoelectronic device would have a size of approximately 5×5 mm². Such display devices can be used for example in “augmented reality” applications.

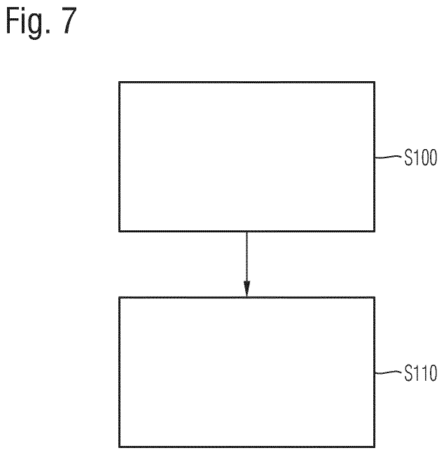

FIG. 7 summarizes a method in accordance with embodiments. A method for producing an arrangement of semiconductor laser devices comprises forming (S100) trenches in a layer stack comprising a first resonator mirror, a second resonator mirror and also an active zone arranged between the first and second resonator mirrors. The method furthermore comprises forming (5110) a charge carrier barrier in an edge region of the active zone.

Although specific embodiments have been illustrated and described herein, those skilled in the art will recognize that the specific embodiments shown and described can be replaced by a large number of alternative and/or equivalent configurations, without departing from the scope of protection of the invention. The application is intended to cover any adaptations or variations of the specific embodiments discussed herein. Therefore, the invention is restricted only by the claims and the equivalents thereof.

1. A semiconductor laser device having a layer stack, comprising
a first resonator mirror,
second resonator mirror and also
an active zone arranged between the first and second resonator mirrors and suitable for emitting electromagnetic radiation,
where a charge carrier barrier (118) is arranged around a central region of the active zone and
wherein the charge carrier barrier is produced by local dopant diffusion by virtue of a doping in the region of the charge carrier barrier being increased in an otherwise undoped or intrinsically doped layer of the active zone and a lateral pn junction arising as a result, and by virtue of local quantum well intermixing being produced by the local dopant diffusion, such that the band gap energy of the active zone in the central region differs from that in the region of the charge carrier barrier.

2. The semiconductor laser device as claimed in claim 1, wherein a part of the layer stack is structured to form a mesa, and the charge carrier barrier is arranged in each case in an edge region of the mesa.

3. The semiconductor laser device as claimed in claim 2, wherein a lateral dimension of the mesa is less than 10 μm.

4-6. (canceled)

7. The semiconductor laser device as claimed in claim 1, wherein the doping in the region of the charge carrier barrier is increased to 1·10¹⁷/cm³ to 5·10¹⁸/cm³, preferably to 5·10¹⁷/cm³ to 1·10¹⁸/cm³.

8. The semiconductor laser device as claimed in claim 1, furthermore comprising a buried oxide layer, wherein the buried oxide layer has an opening in a central region of the semiconductor laser device.

9. An arrangement of semiconductor laser devices as claimed in claim 1, wherein adjacent semiconductor laser devices are separated from one another in each case by trenches.

10. The arrangement (15) as claimed in claim 9, wherein the mesa is delimited by the trenches.

11. The arrangement as claimed in claim 9, wherein the trenches extend at most as far as an upper edge of the active zone and do not sever the active zone.

12. The arrangement as claimed in claim 9, wherein the trenches sever the active zones (110) of adjacent semiconductor laser devices (10).

13. The arrangement as claimed in claim 9, wherein the trenches have a maximum lateral dimension of less than 10 μm.

14. An optoelectronic device comprising an arrangement as claimed in claim 9 and also a control circuit suitable for individually controlling semiconductor laser devices of the arrangement.

15. A display device comprising the optoelectronic device as claimed in claim 14.

16. A method for producing an arrangement of semiconductor laser devices comprising
forming trenches in a layer stack comprising a first resonator mirror, a second resonator mirror and also an active zone arranged between the first and second resonator mirrors, whereby a mesa is structured,
forming a charge carrier barrier in an edge region of the mesa.

17. The method as claimed in claim 16, wherein forming the charge carrier barrier is effected by diffusion of dopants in the region of the trenches.

18. The method as claimed in claim 16, wherein forming the charge carrier barrier is effected by quantum well intermixing in the region of the trenches.

19. The method as claimed in claim 16, wherein the trenches extend at most as far as the upper edge of the active zone.

20. The method as claimed in claim 16, wherein the trenches extend at least as far as the lower edge of the active zone.
